(19) United States
(12) Patent Application Publication
(10) Pub. No.: US 2026/0121761 A1
(43) Pub. Date: Apr. 30, 2026

(54) OPTICAL LINK WITH POLARIZATION-SWITCHED VCSEL MODULATION

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/222,606

(22) Filed: May 29, 2025

Related U.S. Application Data
(63) Continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H04B 10/54; H01S 5/00; H01S 5/183; H04B 10/50

(52) U.S. Cl. CPC H04B 10/54; H01S 5/0071; H01S 5/18305; H04B 10/503

(57) ABSTRACT

A first circuit, which can be a first chiplet, sends electrical data. The electrical data is sent to a vertical-cavity surface-emitting laser (VCSEL). A polarization of the VCSEL is modulated. The modulating can be based on asymmetric current injection. The modulation causes the VCSEL to emit a polarization-modulated beam (PMB). The PMB is based on the data that was sent by the first circuit. The PMB is coupled optically to an optical medium. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit, which can be a second chiplet.

### RELATED APPLICATIONS

This application is a continuation-in-part of U.S. patent application “Hierarchical Redundancy With Parallel Optical Links”Ser. No. 19/211,446, filed May 19, 2025.

The U.S. patent application “Hierarchical Redundancy With Parallel Optical Links” Ser. No. 19/211,446, filed May 19, 2025 is also a continuation-in-part of U.S. patent application “Waveguides Based On Nanoimprint Lithography On A Photonic Wafer Scale Interposer” Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025 is also a continuation-in-part of U.S. patent application “Photonic Wafer-Scale Interposer With Mirrors Based on Nanoimprint Lithography” Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025 is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers” Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins” Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides”Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive”Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to transmitting data and more particularly to an optical link with polarization-switched VCSEL modulation.

### BACKGROUND

The history of communication not only reflects humanity's quest to share and process information, but its creativity and innovation to empower connection. In its most basic form, communication relied on humans talking to one another. Early humans relied on spoken language, using vocal sounds, gestures, and expressions to convey ideas and emotions. Knowledge was often shared via storytelling. However, spoken communication was limited by proximity and memory, prompting the development of more enduring methods. Writing marked a significant leap in communication methods. One of the earliest writing systems was Egyptian hieroglyphs which blended symbolic and phonetic elements. Similar writing systems enabled communication across generations and distances, preserving knowledge beyond the spoken word and stories passed on from generation to generation. Later, the Phoenicians introduced a phonetic alphabet, simplifying writing and laying the foundation for modern writing. These advancements allowed for the exchange of complex ideas through letters and scrolls, carried over vast distances.

The invention of the printing press further revolutionized the way people could communicate. By enabling mass production of pamphlets, books, and so on, the printing press democratized knowledge. Information could now transcend geographic and even social barriers. However, the speed of information transfer remained slow until the discovery of electricity transformed the landscape. Additional technological advancements were quickly realized. For example, the telegraph enabled the transmitting of coded electrical signals over wires, enabling long-distance communication. Soon, transatlantic telegraph cables connected continents and thus people all over the world. The telephone added voice to electrical communication, making real time personal interaction possible over vast distances. The discovery of the radio and later, the television, introduced wireless communication which broadcasted news, entertainment, and even propaganda.

The invention of the computer and the internet enabled global, instantaneous data exchange, from emails to video calls. These technologies leveraged telephone, cable, and even fiber-optic cables transmitting light signals at unprecedented speeds. To support the ever increasing needs of communications, additional technologies were developed including cloud computing and 5G networks, achieving low latency and high efficiency. To power these technologies, communication, high performance processors, systems-on-chip (SoCs), accelerators, and so on were developed, requiring fast communications between chips. Today, this chip-to-chip communication supports the massive computational demands of AI, cloud computing, and 5G networks, achieving unprecedented levels of human communication. From humans talking face-to-face to chips exchanging data at the speed of light, communication's history is a story of innovation. Without a doubt, the future of communications will continue to require technological innovation, including higher bandwidth, lower latency data exchanges.

### SUMMARY

Over time, the demand for processor performance has increased exponentially. Applications such as artificial intelligence (AI), climate modelling, genome sequencing, and so on have continued to push the envelope of what is possible with today's technology including processors, system-on-chips (SoCs), accelerators, servers, memory, power delivery, cooling technologies, and so on. Additional processing performance will certainly be needed. For example, today's large language model (LLM) training time can be measured in months with many processors and accelerators running 24×7. Making further improvements will require advances in all system components. For example, interconnections between processors, accelerators, memory, and so on, must keep pace with the ability of these processing elements to perform calculations. Otherwise, these processing elements can stall. The overall result would be that little, if any, overall performance improvement. Communication bandwidth, speed (latency), and power are critical to overall system performance - both in today's high performance systems and the systems that will be created in the future.

Disclosed techniques enable improved data transmissions. The data transmission is based on an optical link with polarization-switched VCSEL modulation. A first circuit, which can be a first chiplet, sends electrical data. The electrical data is sent to a vertical-cavity surface-emitting laser (VCSEL). A polarization of the VCSEL is modulated. The modulating can be based on asymmetric current injection. The modulation causes the VCSEL to emit a polarization-modulated beam (PMB). The PMB is based on the data that was sent by the first circuit. The PMB is coupled optically to an optical medium. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit, which can be a second chiplet.

A method for transmitting data is disclosed comprising: sending electrical data, by a first circuit, to a vertical-cavity surface-emitting laser (VCSEL); modulating a polarization of the VCSEL, wherein the modulating includes emitting, by the VCSEL, a polarization-modulated beam (PMB), wherein the PMB is based on the electrical data that was sent; coupling optically the PMB to an optical medium, wherein the optical medium is further coupled to a polarization-dependent optical element (PDOE); decoding, by the PDOE, the PMB into the electrical data that was sent; and delivering the electrical data to a second circuit.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for an optical link with polarization-switched VCSEL modulation.

FIG. 2 is a flow diagram for separating a polarization-modulated beam.

FIG. 3 is a cross-section of a VCSEL.

FIG. 4 is a top view of contacts for a VCSEL.

FIG. 5 is a block diagram of an optical link with polarization-switched VCSEL modulation.

FIG. 6 is an apparatus for an optical link with polarization-switched VCSEL modulation.

FIG. 7 is a system diagram for an optical link with polarization-switched VCSEL modulation.

### DETAILED DESCRIPTION

Techniques for transmitting data using an optical link with polarization-switched VCSEL modulation are disclosed. Today's rapidly increasing demand for processing performance continues to push the envelope for processors as well as other system elements. To meet these demands, high performance systems-on-chip (SoCs) have been designed that can include processors, memories, switching elements, and so on. These SoC's can feature transistor counts in the tens of billions. Furthering the ability for system-level performance, accelerators, such as artificial intelligence (AI) accelerators, have been designed to offload and speed up particularly challenging calculations. For example, today's large language models can rely on many such scaled-out accelerators to perform training and inferencing. As raw processing power increases, the need for additional bandwidth and speed to memory elements also increases, leading to advancements such as HBM memories where memory dies can be stacked on a single substrate.

The never-ending drive for performance has also spurred innovation in methods to interconnect system elements. In the past, simple bus architectures such as the Peripheral Component Interconnect (PCI) enabled sufficient bandwidth to keep processor elements from stalling. But as these elements grew in their ability to process more data more efficiently, additional methods of interconnect were developed. For example, high speed serial links such as PCI Express (PCIe) enabled Gigabit-per-second speeds on multiple “lanes”. As processing power has increased, optical communications have become a low power, high bandwidth alternative for transferring data between processing elements. For example, multimode fibers enable remarkably high bandwidth short-reach optical links which can be used between sever racks, switches, storage, and so on.

Optical interconnect solutions have also been pursued to increase on-chip communications. For example, vertical-cavity surface-emitting lasers (VCSELS) can be used to generate light-based communication with a chip, wafer, etc. with lower latency and better bandwidth than traditional metal paths, especially when those paths are long. However, VCSELS have disadvantages which can limit their performance and increase power usage. Traditionally, current is used to modulate a VCSEL. That is, once light is emitted, the intensity of the light can be adjusted by adding additional current. The optical power difference required to recognize a “1” (e.g., “on”) as opposed to a “0” (e.g., “off”) can be described as the extinction ratio of the VCSEL. A high extinction ratio is helpful for signal quality, ease of receiver sensing, and power usage. However, issues exist that can limit the effectiveness of VCSELS as an on-chip, on-wafer, on-interposer, etc. communication device. First, VCSELS can be associated with a threshold current-a minimum level of current which must be sent into the active area of the VCSEL before light can be emitted. This can reduce the extinction ratio and increase power usage. Further, while optical power output (light intensity) of the VCSEL near the threshold can be linear, it can become non-linear as current is increased. Thus, modulating VCSEL intensity with current can lead to increased power usage to maintain a high extinction ratio, especially when many VCSELS are incorporated in a chip, wafer, interposer, and so on.

To address these issues, an optical link with polarization-switched VCSEL modulation is disclosed. Electrical data is sent by a first circuit, which can be a chiplet, an SoC, a wafer, an ASIC, a core, a core on a wafer, and so on to a vertical-cavity surface-emitting laser (VCSEL). The first circuit can be a circuit within a chip, a chiplet, a system-on-chip (SoC), a wafer, etc. A polarization of the VCSEL is modulated. The polarization can be based on asymmetric current injection. The VCSEL emits a polarization-modulated beam (PMB). The PMB is based on the electrical data that was sent. The PMB is coupled optically to an optical medium. The coupling optically can be accomplished by a mirror, such as a TMAH-etched mirror, a grating coupler, and so on. The coupling can include angling the PMB that was emitted by the VCSEL. The angling can be based a micro-optical element (MOE) such as a micro lens, a diffractive optical element, a Fresnel lens, an asymmetric non-focusing optical device, and so on.

The optical medium is further coupled to a polarization-dependent optical element (PDOE). The PDOE can comprise a grating coupler, a polarization filter, a polarization multiplexor (PMUX), and so on. The PDOE decodes the PMB into the electrical data that was sent. In the case of a PMUX, a polarized beam splitter (PBS) can separate the PMB into at least two polarized optical signals. The PBS can be within the PMUX. The separating can be based on a plane of polarization of the PMB. Each polarized optical signal can be transformed by a unique photodiode. The transforming can result in at least two electrical signals. These electrical signals can be assembled into a single electrical signal. The single electrical signal can comprise the electrical data that was sent. The electrical data is delivered to a second circuit, which can be a chiplet, SoC, wafer, ASIC, a core, a core on a wafer, and so on. The second circuit can comprise a circuit within a chip, a chiplet, an SoC, a wafer, etc. The first chiplet, the second chiplet, and the VCSEL can be within a plurality of chiplets bonded to a front side of a photonic wafer-scale integrations interposer (PWSI). The PWSI can include a plurality of waveguides. The optical medium can comprise a waveguide within the plurality of waveguides.

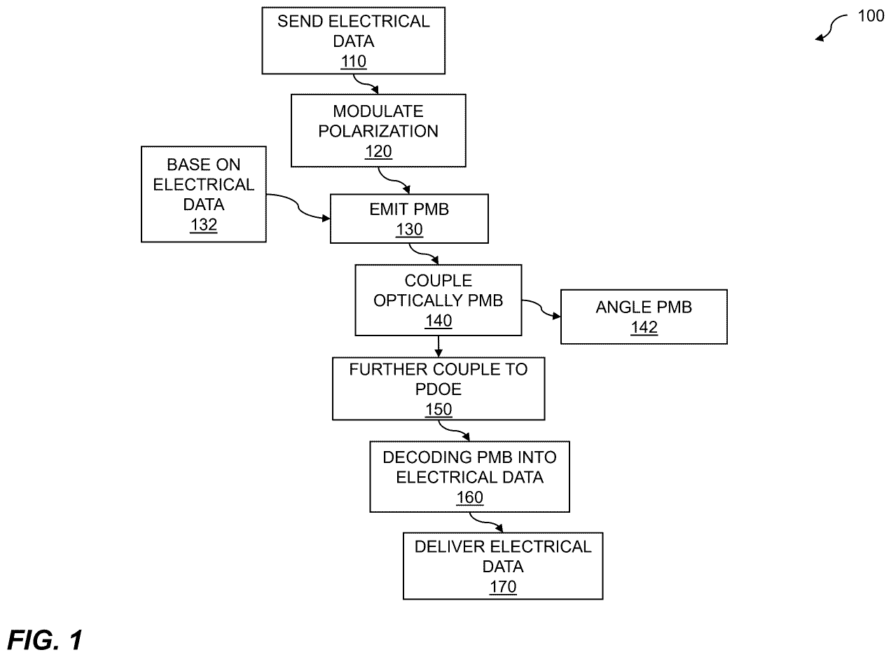

FIG. 1 is a flow diagram for an optical link with polarization-switched VCSEL modulation. The flow 100 includes sending electrical data 110. Embodiments include sending electrical data, by a first circuit, to a vertical-cavity surface-emitting laser (VCSEL). The first circuit, which can be a chiplet, SoC, wafer, interposer, ASIC, and so on, to a vertical-cavity surface-emitting laser (VCSEL). The first circuit can be a circuit within a chip, a core, a chiplet, an SoC, a wafer, an interposer, etc. The first circuit can comprise a processor, chiplet, multi-core processor, memory controller, memory chip such as DDR or HBM, I/O chip, AI accelerator, switching chip, and so on. The first circuit and the VCSEL can be on the same or different circuit boards, interposers, wafers, etc. The sending can be accomplished using any means to communicate between chips. For example, the sending can be based on a routes on a printed circuit board, a bus interface, a wireless communication protocol such as Bluetooth™, metal layers on a wafer or wafer interposer, and so on. The electrical data can comprise serialized data, data packets, handshaking signals, etc. A VCSEL can be a semiconductor laser fabricated on a chip. The fabrication can be based on gallium arsenide or another suitable material. The VCSEL can emit light in a perpendicular direction to the chip. The direction can be up (e.g., away from the chip) or down (e.g., into the chip). When light is emitted down, a window can be provided so that the light can escape through the back of the chip. To aid projection of the light, the substrate of the chip can be thinned. The light that is emitted can be coherent light that is in a wavelength range, such as 850 nm-950 nm. Other ranges are possible.

The flow 100 includes modulating a polarization 120 of the VCSEL. Embodiments include modulating a polarization of the VCSEL, wherein the modulating includes emitting, by the VCSEL, a polarization-modulated beam (PMB), wherein the PMB is based on the electrical data that was sent. Modulation can include adjusting properties of light emission of the VCSEL to encode optical data. For example, modulation can be based on current. Adjusting the current applied to an active region of the VCSEL can turn light emission on and off. When the current is below a threshold, lasing action can be stopped. When current levels return to a level exceeding the threshold, lasing can re-start. As current is increased, a brightness, or optical power, of the VCSEL can be increased. The detection of a presence or absence of light from the VCSEL can be used to encode a “1” or “0” in the form of a light wave.

Modulation can include changing properties of the light that is emitted. For example, modulation can include a mode, wavelength, and so on. Modulation can also include changing a polarization of the light emitted by the VCSEL. Polarization can refer to an orientation of an oscillating light wave. Polarization can include linear polarization, circular polarization, elliptical polarization, etc. Various methods of VCSEL modulation can change the polarization of light that is emitted. In embodiments, the modulation is based on asymmetric current injection. Asymmetric current injection can include sending current into an active region of the VCSEL in a non-uniform way. The non-uniformity can influence the VCSEL to produce polarized light in a first direction. The applied current can be altered to produce polarized light in a second direction. For example, more current can be sent to the x-axis of the active region of the VCSEL to produce a polarization in the X plane. The current can be switched to favor the y-axis of the active region of the VCSEL to produce a polarization in the Y plane. Modulation such as described above can be used to encode optical data. The asymmetric current injection can include a current with a DC offset, a current that includes an asymmetric wave, and the like. In some embodiments, the VCSEL includes a ferroelectric liquid crystal layer (FLC). The FLC can include liquid crystals that can be oriented by an electric field. Applying a voltage to the FLC can influence the polarization of light emitted by the VCSEL. In a usage example, a VCSEL with an FLC can include a bottom and middle Distributed Bragg Reflector (DBR) with the FLC layer on top of the middle layer. A top DBR can be included on top of the FLC layer. Other layouts are possible.

The flow 100, includes emitting a polarization-modulated beam (PMB) 130. A PMB can result from modulating the plane of polarization, as described above. The PMB can comprise an optical signal whose polarization changes over time, thus encoding optical information. The polarization of the beam can be sensed, allowing for the decoding of the information that is sent. Recall that electrical data is sent by a first circuit to a VCSEL. The electrical data can be used to modulate a polarization of the VCSEL by disclosed techniques, resulting in a PBM sent from the VCSEL. Thus, in the flow 100, the PBM is based on the electrical data that was sent 132.

The flow 100 includes coupling optically the PBM 140. Embodiments include coupling optically the PMB to an optical medium, wherein the optical medium is further coupled to a polarization-dependent optical element (PDOE). An optical medium can be any material, space, etc. that allows an optical signal, such as a PBM, to propagate. In embodiments, the optical medium comprises a waveguide. The waveguide can include a waveguide within a wafer, an interposer, and so on. Other optical mediums can be used. In a usage example, a fiberoptic cable is used as an optical medium to send an optical signal from a transmitter to a receiver. In embodiments, the optical medium comprises a polarization maintaining fiber. The polarization maintaining fiber can maintain fidelity of the PMB. The first circuit and the VCSEL can be bonded to a photonic wafer-scale interposer (PWSI) which includes a plurality of waveguides to carry optical signals from one or more VCSELs. The optical medium can comprise a waveguide with the plurality of waveguides. Recall that the VCSEL can emit optical signals, such as the PBM, in a vertical direction. The vertical direction can be down, toward the substrate (and the PWSI to which a VCSEL can be bonded). A waveguide within the PWSI can be oriented horizontally or substantially horizontally. Thus, the PBM can be coupled to the waveguide in order for it to propagate along the waveguide to another circuit bonded to the PWSI, such as a second chiplet.

In embodiments, the coupling optically is accomplished by a grating coupler. The grating coupler can diffract light at specific frequencies, input angles, etc. thereby providing efficient transfer of light at a specific frequency into or out of a waveguide. To aid the coupling to a grating coupler, the PBM emitted from the VCSEL can be angled 142. Embodiments include angling the PMB that was emitted by the VCSEL, wherein the angling is based on a micro-optical element (MOE). The MOE can be based on one or more optical techniques. For example, the MOE can comprise a micro lens. The micro lens can be coupled to the first surface-emitting light source such as a VCSEL, an LED, and so on. The micro lens can pre-angle the emitted light. The MOE can comprise a diffractive optical element. The diffractive optical element can create a light phase profile that can focus, shape, or split the emitted light. The MOE can include a Fresnel lens. The Fresnel lens can use concentric grooves or rings to focus the emitted light. The MOE can include an asymmetric non-focusing optical device. The asymmetric non-focusing optical device can enable light to transmit through the device preferentially, where the light can pass through more easily in one direction than another direction. The asymmetric non-focusing optical device can couple light to a waveguide and can suppress a portion of reflected light back to the surface-emitting light source. Any number and/or types of MOEs can be used in conjunction with any number of VCSELS.

Other methods of coupling the PMB to an optical medium, such as a waveguide, can be implemented. In embodiments, the coupling optically is accomplished by a mirror. The mirror can include a mirror within a circuit, a chip, a wafer, an interposer, and so on. In a usage example, the coupling is based on a crystallographic etched mirror. The crystallographic etched mirror can comprise a tetramethylammonium hydroxide (TMAH) etched mirror. The TMAH mirror can reflect incoming light at a 54.74 degree angle to the waveguide. Other angles are possible with various crystallographic etched mirrors. A crystallographic etched mirror can operate in combination with a MOE, such as described above, which can be placed over or near an aperture of the VCSEL. For example, the MOE can pre-angle light from the VCSEL so that when the light is reflected by the TMAH mirror, it is efficiently coupled directly into the waveguide at 90 degrees, or sufficiently close to 90 degrees, from the light source. The coupling can be based on a bent waveguide. The bent waveguide can include a high containment region of a waveguide. The high containment waveguide can redirect the light while minimizing loss of light in the region of the bend of the waveguide. The coupling can be based on an off-axis diffractive lens. An off-axis diffractive lens can direct light at an angle with respect to the optical axis of the lens.

In the flow 100, the optical medium is further coupled to a polarization-dependent optical element (PDOE) 150. A PDOE can be an optical element that interprets a polarization state of an optical signal. The PDOE can be used to decode the PMB at the far end of the optical signal. The flow 100 includes decoding the PMB into electrical data 160. Embodiments include decoding, by the PDOE, the PMB into the electrical data that was sent. The PDOE can be based on a variety of optical techniques. In some embodiments, the PDOE comprises a grating coupler. The grating coupler can separate different polarizations from each other. In a usage example, the separated polarizations of light can be sent to optical receivers, where the optical receivers can convert the optical data to electrical data. In other embodiments, the PDOE comprises a polarization filter. A polarization filter can enable passage of light with a polarization that is compatible with the polarization filter while substantially blocking light with polarizations that are incompatible with the polarization filter. In a usage example, a first polarization filter passes light polarized with a first polarization, and a second polarization filter passes light polarized with a second polarization. In some embodiments, the PDOE comprises a polarization multiplexor (PMUX). The PMUX can receive light that includes two or more polarizations. The received light can be separated into two or more beams, where each beam is based on a single polarization (explained in further detail below).

The flow 100 includes delivering electrical data 170. Embodiments include delivering the electrical data to a second circuit. As the case with the first circuit, the second circuit can be a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The second circuit and the first circuit can be on the same or different circuit boards, interposers, wafers, etc. The electrical data can be delivered to the second circuit using a variety of techniques. The delivery techniques can be based on using wire, interconnect, metal layers, and so on. The metal layers can include metal layers within a circuit board, a wafer, an interposer, and so on. The interposer can include a photonic wafer-scale interposer. The metal layers, which enable interconnection between and among circuits, chiplets, and other elements, can be fabricated on or within a circuit board, wafer, or interposer. As was the case for sending the data from the first circuit to the VCSEL, using the metal layers can offer significant inter-chiplet communications speed due to short wire lengths, and reduced “parasitics” such as resistance, capacitance, and inductance. The second circuit can process the delivered data, forward the delivered data, etc.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

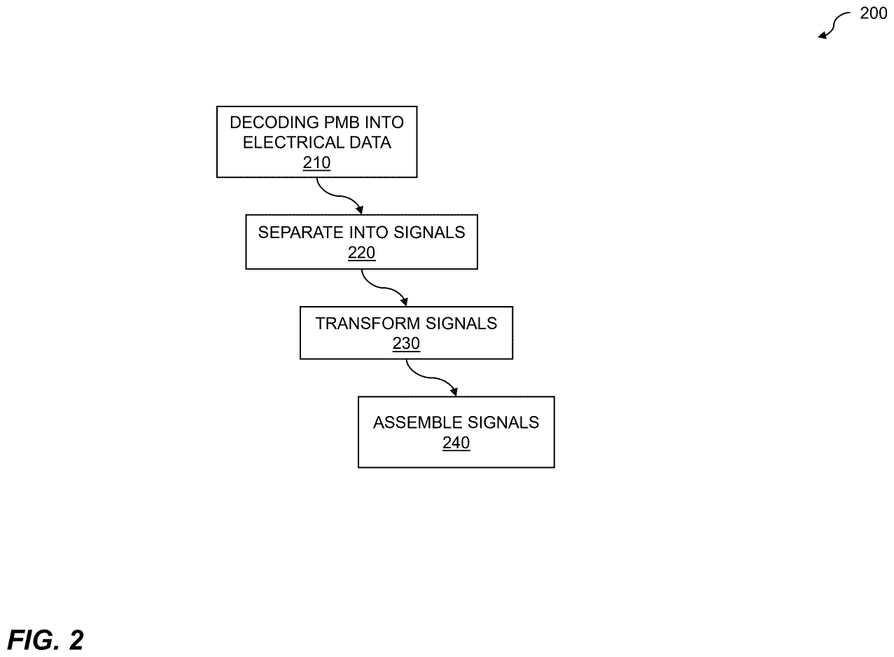

FIG. 2 is a flow diagram for separating a polarization-modulated beam. Data is transmitted between a first circuit and a second circuit. The transmitting data is accomplished by sending the data to a vertical-cavity surface-emitting laser (VCSEL). The VCSEL emits light that is based on the sent data. The light that is emitted by the VCSEL is a polarization-modulated beam (PMB). The modulating is based on asymmetric current injection. The PMB is coupled to an optical medium which transmits the data to a polarization-dependent optical element (PDOE). The PDOE decodes the PMB into the electrical data that was sent. The decoding is accomplished by separating the polarization-modulated beam. The decoded data is delivered as electrical data to a second circuit. The separating a polarization-modulated beam enables an optical link with polarization-switched VCSEL modulation.

The flow 200 includes decoding 210, by the PDOE, the PMB into the electrical data that was sent. Recall that the polarization-modulated beam (PMB) can be created by injecting an asymmetric current into the VCSEL. The asymmetric current can be based on the data that was sent by the first circuit. The PMB includes one or more polarizations of light.

When more than one polarization of light is present within the PMB, the polarizations of light can be separated from each other. Recall also that the PDOE can comprise polarization multiplexor (PMUX). The PMUX can comprise various elements to decode a PMB sent from a polarization-modulated VCSEL through an optical medium such as a waveguide. In embodiments, the PBS is within the PMUX.

In embodiments, the decoding includes separating 220, by a polarized beam splitter (PBS), the PMB into at least two polarized optical signals, wherein the separating is based on a plane of polarization of the PMB. A polarized beam splitter can substantially pass light with a polarization that is compatible with the polarization of the beam splitter and can substantially block light that is incompatible with the polarization of the beam splitter. The PBS can separate the beam based on reflection and transmission of the incoming polarized light. The reflected path and the transmitted path can comprise at least two optical signals. In a usage example, the PBS can direct x-polarized light, which can be called light polarized at 0 degrees, to a transmitted path and direct y-polarized light, which can be called light polarized at 90 degrees, to a reflected path. Other modes of polarization can be used. In another usage example, the polarized beam splitter can pass light that is polarized with an s-polarization and can reflect light that is polarized with a p-polarization. Recall that an s-polarization includes polarization that is normal or perpendicular to a surface of incidence, and a p-polarization includes polarization that is parallel to a surface of incidence. Additional states of polarization can be used in modulation such that the PBS can split the PMB into more than 2 optical signals. The PBS can be a separate optical element or can be incorporated into another optical element.

The flow 200 includes transforming 230 signals. Embodiments include transforming each optical signal within the at least two polarized optical signals, by a unique photodiode, to an electrical signal, wherein the transforming results in at least two electrical signals. The at least two electrical signals are based on the data that was sent. In a usage example, the polarization beam splitter discussed above can send polarizations of light in different directions. In a usage example, a PMB includes an s-polarized beam and a p-polarized beam. The s-polarized beam passes through the PBS and the p-polarized beam is reflected at an angle away from the s-polarized beam. In another usage example, a first electrical signal can represent a logical one and a second electrical signal can represent a logical zero. In another usage example, the first electrical signal and the second electrical signal represent different serial electrical data streams that were sent.

The flow 200 further includes assembling signals 240. Embodiments include assembling the at least two electrical signals into a single electrical signal, wherein the single electrical signal comprises the electrical data that was sent. The two signals can be combined. For example, when the first signal is high, a “1” can be sent on the combined signal. When the second signal is high, a “0” can be sent on the combined signal. Other means of combination are possible. The assembled electrical signal can include electrical data such as serial electrical data. The assembled electrical data is delivered to a second circuit. The second circuit can process the data, switch the data to another circuit, and the like. In a usage example, the assembling the at least two electrical signals is accomplished using a retiming technique.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

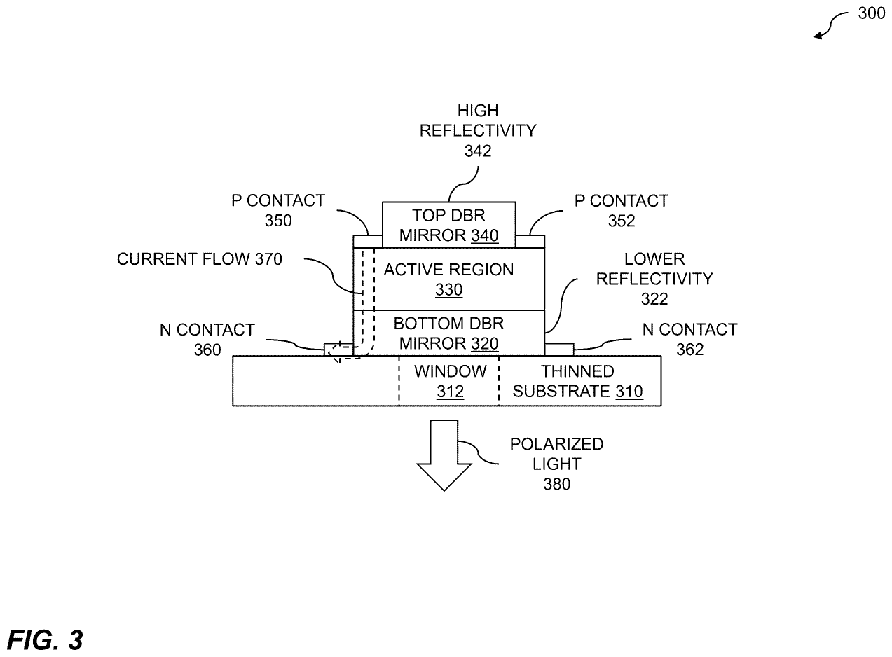

FIG. 3 is a cross-section of a VCSEL. A VCSEL enables optical links with polarization-switched modulation. A first circuit, which can be a first chiplet, sends electrical data. The electrical data is sent to a vertical-cavity surface-emitting laser (VCSEL). A polarization of the VCSEL is modulated. The modulating can be based on asymmetric current injection. The modulation causes the VCSEL to emit a polarization-modulated beam (PMB). The PMB is based on the data that was sent by the first circuit. The PMB is coupled optically to an optical medium. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit, which can be a second chiplet.

The block diagram 300 includes a thinned substrate 310. The thinned substrate can include a variety of materials suitable to fabricating a VCSEL. In a usage example, the substrate can include a gallium-arsenide (GaAs) substrate. Other materials that can be used for the substrate can include aluminum-gallium-arsenide (AlGaAs), germanium (Ge), sapphire, and so on. The substrate can be thinned to enable fabrication of an aperture or window 312. The thinning of the substrate can be accomplished by grinding, polishing, etching, and so on. Light in the form of a polarization-modulated beam (PMB) is emitted by the VCSEL. The light emitted by the VCSEL can exit the VCSEL by passing through the window in the thinned substrate.

The VCSEL structure consists of an active region that is placed between two highly reflective mirrors. The first mirror includes a first reflectivity, and the second mirror includes a second reflectivity. In a usage example, the two highly reflective mirrors can be based on Distributed Bragg Reflectors (BDRs). These mirrors can be formed from multiple, alternating layers of materials, where the materials have different refractive indices. In the block diagram 300, a Distributed Bragg Reflector mirror can include a bottom mirror 320. The bottom mirror can include an n-Distributed Bragg Reflector. The bottom mirror can include a reflectivity that is lower than a top mirror (described below). In a usage example, the reflectivity 322 of the bottom DBR can include a reflectivity of 93 percent to 99 percent, or another suitable reflectivity. The n-Distributed Bragg Reflectors associated with the bottom mirror can be insulated from other layers in the block diagram by an oxide layer (not shown).

The block diagram 300 includes an active region 330. The active region can comprise a region in which light that is emitted by the VCSEL can be generated. The light can be generated using a variety of techniques. In a usage example, the active region can include a structure such as a quantum well structure. The active region can be located within a laser cavity. The block diagram 300 can include an additional oxide layer (not shown) between the active region and a top DBR mirror. The oxide layer between the bottom mirror and the active area, and the oxide layer between the active layer and the top mirror may or may not be present in the VCSEL. When present, the oxide layers can confine the light and electrical current within the active area. The block diagram 300 includes p-Distributed Bragg Reflector mirror 340. In the block diagram 300, the p-Distributed Bragg Reflector mirror comprises the top mirror of the VCSEL. The top mirror can include a high reflectivity 342. In a usage example, the reflectivity of the top DBR can include a reflectivity of 99.4 percent to 99.9 percent. Other suitable reflectivities can be implemented.

An electrical current is applied to the VCSEL in order for the VCSEL to lase in order to emit coherent light. The applied electrical current can include a DC current, a pulsed current, and so on. The current can include a symmetrical current, an asymmetrical current, etc. The applied current can modulate the light emitted by the VCSEL. In embodiments, modulating is based on asymmetric current injection. An injected asymmetrical current can include a current that is unbalanced or unequal with respect to distribution and/or direction. In a usage example, the current is asymmetrical about the x-axis, that is, the asymmetrical current has a DC offset. The injection of the asymmetrical current can cause the modulated light emitted by the VCSEL to include a polarization. Changing the injected asymmetrical current can change the polarization of the emitted light. The electrical current can be applied to the top p-contact. The p-contact can include a single contact, a ring contact, a “broken ring” contact where the ring is broken into two or more segments, and so on. In the block diagram 300, the contact includes one or more p-contacts such as p-contact 350 and p-contact 352.

In embodiments, the VCSEL includes a ferroelectric liquid crystal layer (FLC). The FLC can include liquid crystals that can be oriented by an electric field. Applying a voltage to the FLC can influence the polarization of light emitted by the VCSEL. In a usage example, a VCSEL with an FLC can include a bottom DBR, a middle DBR with the FLC layer on top of the middle layer. A top DBR can be included on top of the FLC layer. Other layouts are possible.

The electrical current can exit the bottom of the VCSEL via one or more n-contacts. The n-contacts can include a single contact, a ring contact, a broken ring contact, etc. In the block diagram 300, the one or more n-contacts include n-contact 360 and n-contact 362. In a usage example, a p-contact ring and an n-contact ring can be concentric broken rings. By accessing a portion of the p-contact ring and the opposite (e.g., diagonally opposite) n-contact ring a first polarization can be achieved. By accessing the previously unused portion of the p-contact and the previously unused portion of the n-contact, a second polarization can be achieved. In these cases, the electrical current flows 370 from a first p-contact to a second n-contact (e.g., diagonal opposites), from a second p-contact to a first n-contact, and so on. The VCSEL emits light 380. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing optical coupling of the polarization-modulated beam (PMB). Embodiments include angling the PMB that was emitted by the VCSEL, wherein the angling is based on a micro-optical element (MOE). The MOE can include a micro lens, a diffractive optical element, a Fresnel lens, an asymmetric non-focusing optical device, and so on.

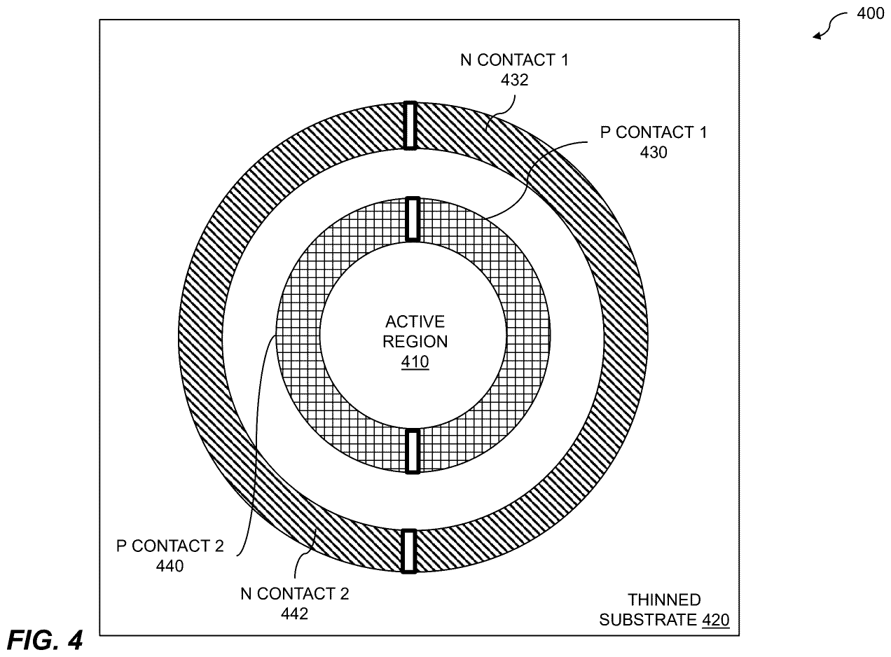

FIG. 4 is a top view of contacts for a VCSEL. Described previously, modulating a polarization of a vertical-cavity surface-emitting laser (VCSEL) enables polarization-switched optical links. A first circuit sends electrical data. The electrical data is sent to a vertical-cavity surface-emitting laser (VCSEL). A polarization of the VCSEL is modulated. The modulating can be based on asymmetric current injection. An injected asymmetrical current is a current that is unbalanced or unequal with respect to distribution and/or direction. The distribution and/or direction of the current can duration during which the current is positive, the current is negative, and so on. In a usage example, a current is asymmetrical about the x-axis, resulting in the asymmetrical current having a DC (e.g., nonzero) offset. The injection of the asymmetrical current can cause the VCSEL to emit modulated light that includes a phase. Thus, changing the injected asymmetrical current can change the polarization of the modulated, emitted light. The changing the injection of the asymmetrical current can be accomplished using contacts associated with the VCSEL. The contacts can include n-contacts and p-contacts, where the n-contacts are based on an n-type diffusion or implantation, and the p-contacts are based on a p-type diffusion or implantation. The n-contacts and the p-contacts enable an optical link with polarization-switched VCSEL modulation. The modulation causes the VCSEL to emit a polarization-modulated beam (PMB). The PMB is based on the data that was sent by the first circuit. The PMB is coupled optically to an optical medium. The optical medium comprises a waveguide. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit.

The FIG. 400 shows an active region 410 of the VCSEL. Light to be emitted by the VCSEL is generated within the active region. The active region can include a structure such as a quantum well structure. The FIG. 400 shows n-contacts and p-contacts associated with a VCSEL. A top view of the VCSEL shows a thinned substrate 420. The thinned substrate can comprise a variety of materials suitable to fabricating a VCSEL such as a gallium-arsenide (GaAs) substrate. Other materials that can be used for the substrate can include aluminum-gallium-arsenide (AlGaAs), germanium (Ge), sapphire, and so on. The substrate can be thinned using a variety of fabrication techniques can be accomplished by grinding, polishing, etching, and so on. The FIG. 400 shown p-contacts and n-contacts. The contacts can be configured based on various geometries such as rings, squares, and so on. The contacts can be based on a variety of contacts. In the figure, a p-contact comprises two segments, p-contact 1 430 and p-contact 2 440. The p-contact can include any number of segments. Also, in the figure, the n-contact comprises two segments, n-contact 1 432 and n-contact 2 442. The n-contact can also include any number of segments.

Modulating the polarization of the light emitted by the VCSEL can be accomplished using asymmetric current injection into one or more p-contacts and one or more n-contacts. The asymmetric current can be injected using opposite pairs of p-contacts and n-contacts, for example, p-contact 1 and n-contact 2 or p-contact 2 and n-contact 1. Different polarization-modulated beams (PMBs) can be emitted by the VCSEL depending on which p-contacts and which n-contacts are used for the current injection. Alternatively, current can be applied to the VCSEL using all of the p-contacts and all of the n-contacts, a portion of the p-contacts and a portion of the n-contacts, adjacent p-contacts and n-contacts (such as p-contact 1 and n-contact 1), and so on.

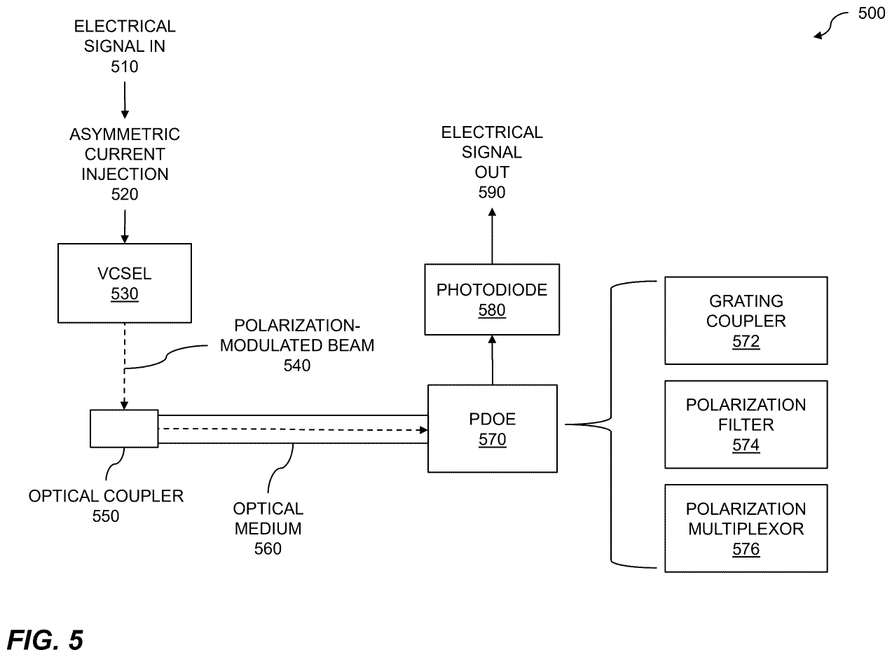

FIG. 5 is a block diagram of an optical link with polarization-switched VCSEL modulation. A polarization-switched optical link enables transmitting data between a first circuit and a second circuit. A first circuit sends electrical data. The electrical data is sent to a vertical-cavity surface-emitting laser (VCSEL). A polarization of the VCSEL is modulated. The modulating can be based on asymmetric current injection. The modulation causes the VCSEL to emit a polarization-modulated beam (PMB). The PMB is based on the data that was sent by the first circuit. The PMB is coupled optically to an optical medium. The optical medium comprises a waveguide. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit.

The block diagram 500 includes an electrical signal in 510. The electrical signal can represent data such as image data, video data, and audio data; artificial intelligence (AI) weights, biases, and data; and so on. The electrical signal can represent parallel data such as data set as bytes, words, etc. The electrical data can represent serial data. The block diagram 500 includes asymmetric current injection 520. The asymmetric current injection can comprise the basis for modulating a polarization of a vertical-cavity surface-emitting laser (VCSEL). In a usage example, the modulating the polarization of the VCSEL can include s-polarization. In a second usage example, the polarization of the VCSEL can include p-polarization. The asymmetric current can be applied to a VCSEL 530. The asymmetric current can be applied to contacts associated with the VCSEL in order to polarize the output of the VCSEL. In the block diagram 500, the modulating includes emitting, by the VCSEL, a polarization-modulated beam (PMB) 540, wherein the PMB is based on the electrical data that was sent. The PMB can be directed toward an optical coupler 550. The optical coupler can include a coupler on or within a circuit board, a wafer, an interposer, etc. The optical coupler can be based on a variety of optical elements, techniques, and so on. In embodiments, the coupling optically is accomplished by a grating coupler. The grating coupler can include a periodic grating that can transfer the PMB with low loss into the optical medium. In other embodiments, the coupling optically is accomplished by a mirror. In a usage example, the mirror can include a nano-imprint lithography mirror. Embodiments include angling the PMB that was emitted by the VCSEL, wherein the angling is based on a micro-optical element (MOE) (not shown). The angling the PMB can be used to complement an angle associated with the coupling the PMB to the optical medium.

The block diagram includes an optical medium 560. The optical medium can include a media that is capable of transferring the PMB coupled to the optical medium by the optical coupler. The optical medium can include a waveguide on or within a wafer, an interposer, and so on. In embodiments, the optical medium comprises a polarization maintaining fiber. The block diagram 500 includes a polarization-dependent optical element (PDOE) 570 to which the optical medium is further coupled. The PDOE can be based on a variety of optical elements, optical techniques, and so on. The PDOE can separate different polarizations of light from the PMB. The separated polarizations of light (e.g., optical data) can be decoded into electrical data that was sent by the first circuit. The PDOE can accomplish decoding the PMB based on a variety of decoding techniques. In embodiments, the PDOE comprises a grating coupler 572. The grating coupler can separate different polarizations from each other. In a usage example, the separated polarizations of light can be sent to optical receivers, where the optical receivers can convert the optical data to electrical data. In another usage example, the grating coupler can indicate when a first polarization is active in the optical medium, which can comprise a “1”. The absence of the signal from the grating coupler can comprise a “0”.

Clocking, such as clock and data recovery (CDR) circuits can synchronize the PMB with the receiving and/or decoding circuits.

In other embodiments, the PDOE comprises a polarization filter 574. A polarization filter can enable passage of light with a polarization that is compatible with the polarization filter while substantially blocking light with polarizations that are incompatible with the polarization filter. In a usage example, a first polarization filter passes light polarized with a first polarization. CDR circuits can again be used to coordinate an output to be sent to a second circuit. In another usage example, a second polarization filter passes light polarized with a second polarization. In this case, the two signals can be reformed into a single signal. In further embodiments, the PDOE comprises a polarization multiplexor (PMUX) 576. The PMUX can receive light that includes two or more polarizations. The received light can be separated into two or more beams where each beam is based on a single polarization. In embodiments, the decoding includes separating, by a polarized beam splitter (PBS), the PMB into at least two polarized optical signals, wherein the separating is based on a plane of polarization of the PMB. In a usage example, the beam splitter can reflect light associated with a first polarization and transmit light associated with a second polarization. In embodiments, the PBS is within the PMUX.

Embodiments include transforming each optical signal within the at least two polarized optical signals, by a unique photodiode, to an electrical signal, wherein the transforming results in at least two electrical signals. The block diagram 500 includes a photodiode 580. More than one photodiode can be included, where each photo diode can transform or decode an optical signal into an electrical signal. In the block diagram 500, the PDOE decodes the PMB into the electrical data that was sent. The decoded PMB is sent as an electrical signal out 590. Discussed previously, each optical signal within the at least two polarized optical signals is transformed by a unique photodiode to an electrical signal. The transforming results in at least two electrical signals. Further embodiments include assembling the at least two electrical signals into a single electrical signal, wherein the single electrical signal comprises the electrical data that was sent. The single electrical signal that includes the electrical data that was sent can be sent to a destination element such as a circuit, chiplet, SoC, ASIC, wafer, interposer, etc. The destination element can include a processor, an AI accelerator chiplet, a switching chiplet, etc.

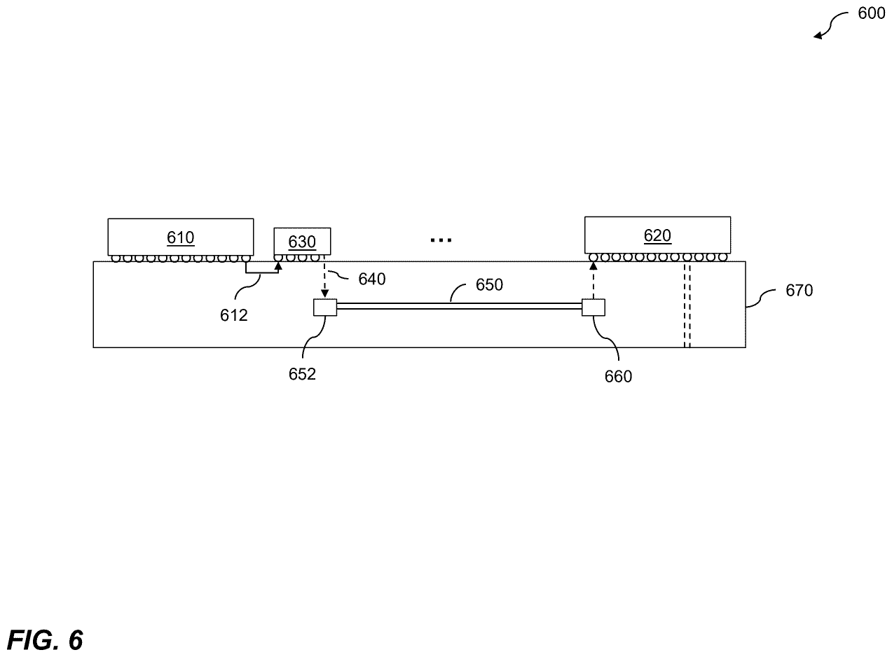

FIG. 6 is an apparatus for an optical link with polarization-switched VCSEL modulation. An optical link can be established that enables transmitting data. The optical link can be used to send data from a first circuit to a second circuit. The first circuit and the second circuit can be collocated on a circuit board, wafer, or interposer; located in different multiprocessors; located in different datacenters; and so on. In embodiments, a first circuit sends electrical data to a vertical-cavity surface-emitting laser (VCSEL). The VCSEL converts electrical data into optical data (e.g., light data). The VCSEL modulation includes emitting, by the VCSEL, a polarization-modulated beam (PMB). The PMB is based on the electrical data that was sent. By coupling the modulated beam to an optical medium such as a waveguide, a fiber, and so on, the PMB is sent via the optical medium to a polarization-dependent optical element (PDOE). The PDOE decodes the PMB to electrical data. The electrical data is delivered to the second circuit. The apparatus enables transmitting data using an optical link with polarization-switched VCSEL modulation.

An apparatus is disclosed for transmitting data comprising: a first circuit, wherein the first circuit sends electrical data to a vertical-cavity surface-emitting laser (VCSEL), and wherein the VCSEL emits a polarization-modulated beam (PMB) based on asymmetrically injecting current into an active region within the VCSEL; an optical medium, wherein the PMB is coupled optically, via an optical coupler, to the optical medium; a polarization-dependent optical element (PDOE), wherein the PDOE is further coupled to the optical medium, wherein the PDOE decodes the PMB into the electrical data that was sent; and a second circuit, wherein the second circuit receives the electrical data that was sent.

The apparatus 600 includes a first circuit 610, wherein the first circuit sends electrical data to a vertical-cavity surface-emitting laser (VCSEL), and wherein the VCSEL emits a polarization-modulated beam (PMB) based on asymmetrically injecting current into an active region within the VCSEL. The first circuit can be a chiplet, SoC, wafer, interposer, ASIC, and so on. The first circuit can be a circuit within a chip, a chiplet, a core, a core on a wafer, an SoC, a wafer, interposer, etc. The first circuit can comprise a processor, multi-core processor, memory controller, memory chip such as DDR or HBM, I/O chip AI accelerator, switching chip, and so on. The first chip sends data to a second circuit 620 using the VCSEL and additional optical elements. The circuits, which can be chiplets, can be connected, attached, bonded, or otherwise coupled to a circuit board, a wafer, an interposer, and so on.

The apparatus further includes a first vertical-cavity surface-emitting laser (VCSEL) 630. While two chiplets and one VCSEL are shown, the apparatus can include any number of circuits, chiplets, SoCs, wafers, etc. and any number of VCSELs. The circuits can include AI accelerators, switching chiplets, ASICS, I/O chips, and so on. The first circuit sends 612 electrical data to the VCSEL. The VCSEL emits a polarization-modulated beam (PMB). The PMB 640 can include a beam with a plurality of polarizations. In a usage example, the PMB can include two polarizations, where one polarization represents a logic one and the second polarization represents a logic zero. In another usage example, two polarizations can represent two different serial data streams. The first circuit can send data surface-emitting light sources that can be modulated such as light emitting diodes (LEDs), laser diodes (LDs), and the like.

The PMB emitted by the VCSEL is conveyed to an optical coupler 652. The apparatus 600 includes an optical medium 650, wherein the PMB is coupled optically, via an optical coupler, to the optical medium. The optical medium can include a low loss optical medium appropriate for sending the PMB. In embodiments, the optical medium comprises a waveguide. The optical medium can also include an optical fiber. In embodiments, the optical medium comprises a polarization maintaining fiber. The optical coupler can comprise a grating coupler. The grating coupler can include a periodic grating that can transfer the PMB with low loss into the optical medium. The optical coupler can comprise a mirror. In a usage example, the mirror can include a nano-imprint lithography mirror. Embodiments include angling the PMB that was emitted by the VCSEL, wherein the angling is based on a micro-optical element (MOE). The angling the PMB can be used to complement an angle associated with the coupling the PMB to the optical medium. The angling can also compensate for variations in a wafer or interposer across the surface of the wafer or interposer. In a usage example, the PMB emitted by VCSEL can be pre-angled to an angle such as 9.74 degrees and a mirror such as a crystallographic etched mirror can include an angle, such as 54.74 degrees. The combination of pre-angling and angling can enable coupling the PMB to a waveguide at an angle substantially normal to an entrance aperture of the waveguide.

The MOE can be based on one or more optical techniques. In embodiments, the MOE can comprise a micro lens. The micro lens can be coupled to a first surface-emitting light source such as the VCSEL, a laser diode (LD), an LED, and so on. The micro lens can pre-angle the emitted light. In embodiments, the MOE can comprise a diffractive optical element. The diffractive optical element can create a light phase profile that can focus, shape, or split the emitted light. In embodiments, the MOE can comprise a Fresnel lens. The Fresnel lens can use concentric grooves or rings to focus the emitted light. In embodiments, the MOE can comprise an asymmetric non-focusing optical device. The asymmetric non-focusing optical device can enable light to transmit through the device preferentially, where the light can pass through more easily in one direction than another direction. The asymmetric non-focusing optical device can couple light to an optical medium such as a waveguide and can suppress a portion of reflected light back to the surface-emitting light source.

The apparatus 600 includes a polarization-dependent optical element (PDOE) 660, wherein the PDOE is further coupled to the optical medium, wherein the PDOE decodes the PMB into the electrical data that was sent. The PDOE can separate different polarizations of light from the PMB. The separated polarizations of light (e.g., optical data) can be decoded into electrical data that was sent by the first circuit. As described above and throughout, the PDOE can accomplish decoding based on a plurality of decoding techniques such as a grating coupler, a polarization filter, a polarization mux, and so on.

The apparatus 600 includes a second circuit 620, wherein the second circuit receives the electrical data that was sent. The second circuit can receive that transmitted data that was sent by the first circuit. The second circuit can be a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The first circuit and the second circuit can be located on a different or common circuit board, a different or common wafer, a different or common rack, and so on. The first circuit and the second circuit can be remotely located with respect to each other. “Remotely located” can include locating the first circuit and the second circuit in separate circuit boards or wafers; separate multiprocessors, separate data racks, separate data centers, and so on. As shown in the apparatus 600, the first circuit, the second circuit, and the VCSEL can be coupled to a photonic wafer-scale interposer (PWSI) 670. In embodiments, the first circuit and the second circuit comprise a first chiplet and a second chiplet, respectively. In embodiments, the first chiplet, the second chiplet, and the VCSEL are within a plurality of chiplets bonded to a front side of a photonic wafer-scale interposer (PWSI), wherein the PWSI includes a plurality of waveguides, and wherein the optical medium comprises a waveguide within the plurality of waveguides. The PWSI can enable high-speed communication between and among circuits, chiplets, etc. and VCSELs coupled to the PWSI. The PWSI can be configured to accomplish a variety of processing tasks. In embodiments, the PWSI comprises an optical wafer-scale AI accelerator, wherein one or more chiplets within the plurality of chiplets comprise one or more artificial intelligence (AI) accelerators. The AI accelerators can be used for training AI models and machine learning (ML) models, executing the AI models and the ML models, and the like.

The AI models and ML models can be applied to processing applications such as video and image processing; audio processing and voice recognition; etc. In other embodiments, the PWSI comprises an optical wafer-scale network switch, wherein one or more chiplets within the plurality of chiplets comprise one or more switching chiplets. The optical wafer-scale network switch can be used for accessing and transferring large amounts of data such as data associated with training AI models and ML models. The optical wafer-scale network switch can transfer data to be processed by the trained models.

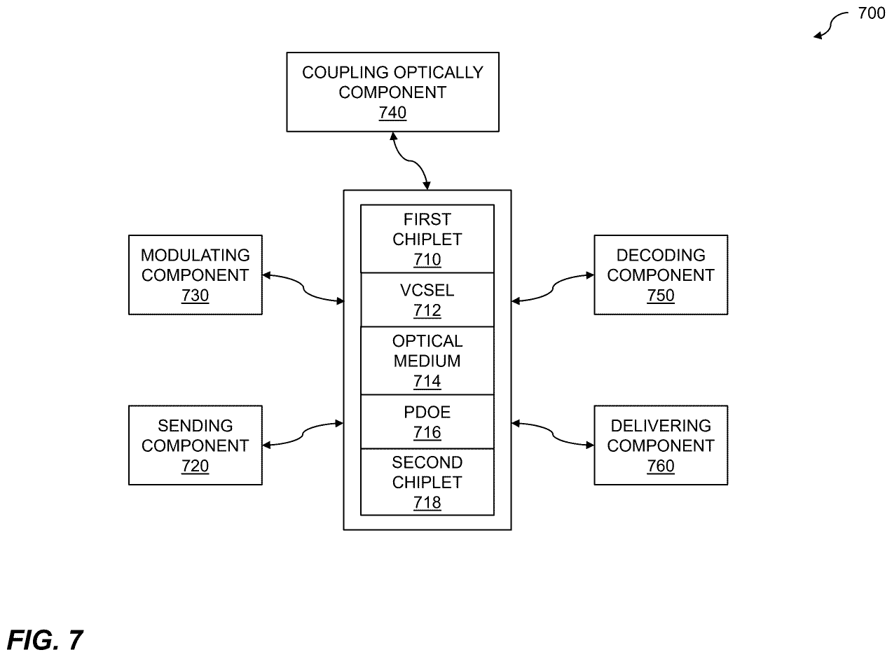

FIG. 7 is a system diagram for an optical link with polarization-switched VCSEL modulation. A first circuit sends electrical data. The electrical data is sent to a vertical-cavity surface-emitting laser (VCSEL). A polarization of the VCSEL is modulated. The modulating can be based on asymmetric current injection. The modulation causes the VCSEL to emit a polarization-modulated beam (PMB). The polarization can include s-polarization where the electric field oscillates normal (e.g., perpendicular) to a plane of incidence, p-polarization where the electric field oscillates parallel to a plane of incidence, etc. The PMB is based on the data that was sent by the first circuit. The PMB is coupled optically to an optical medium. The optical medium comprises a waveguide. The coupling optically can be accomplished using a grating coupler or a mirror. The optical medium is further coupled to a polarization-dependent optical element (PDOE). The PDOE decodes the PMB into the electrical data that was sent. The electrical data is delivered to a second circuit. The second circuit can be collocated within a plurality of circuit that also includes the first circuit. The second circuit can be located remotely from the first circuit. The sending, modulating, coupling, decoding, and delivering enable an optical link with polarization-switched VCSEL modulation.

Disclosed is a system for transmitting data comprising: a first circuit, wherein the first circuit is coupled to a vertical-cavity surface-emitting laser (VCSEL); an optical medium, wherein light emitted from the VCSEL is coupled optically, via an optical coupler, to the optical medium; a polarization-dependent optical element (PDOE), wherein the PDOE is further coupled to the optical medium; and a second circuit; wherein the system is configured to: send electrical data, by the first circuit, to the VCSEL; modulate a polarization of the VCSEL, wherein the modulating includes emitting, by the VCSEL, a polarization-modulated beam (PMB), wherein the PMB is based on the electrical data that was sent; couple optically the PMB to the optical medium; decode, by the PDOE, the PMB into the electrical data that was sent; and deliver the electrical data to the second circuit.

The system 700 includes a first circuit 710, wherein the first circuit is coupled to a vertical-cavity surface-emitting laser (VCSEL) 712. The first circuit can include a chiplet within a plurality of chiplets. The chiplets can include processor chiplets, memory chiplets, AI accelerator chiplets, switching chiplets, I/O chiplets, and the like. The VCSEL can include a VCSEL within a plurality of VCSELs. Other surface-emitting light sources can also be used. In a usage example, a surface-emitting light source can include a light emitting diode (LED), a laser diode, and so on. The system 700 includes an optical medium 714, wherein light emitted from the VCSEL is coupled optically, via an optical coupler, to the optical medium. The optical medium can include an optical fiber, an optical waveguide, and so on. In embodiments, the optical medium comprises a polarization maintaining fiber. Various optical elements can be used as an optical coupler to optically couple a polarization-modulated beam (PMB) to the optical element. The coupling optically can be accomplished using an optical coupler. The optical coupler can comprise a grating coupler. The grating coupler can include a periodic grating that can transfer the PMB with low loss into the optical medium. The optical coupler can comprise a mirror. In a usage example, the mirror can include a nano-imprint lithography mirror. Embodiments include angling the PMB that was emitted by the VCSEL, wherein the angling is based on a micro-optical element (MOE). The angling the PMB can be used to complement an angle associated with the coupling the PMB to the optical medium.

The system 700 includes a polarization-dependent optical element (PDOE) 716, wherein the PDOE is further coupled to the optical medium. The PDOE can distinguish between different polarizations of light from the PMB emitted by the VCSEL. The PDOE can separate different polarization of light. The separated polarizations of light can be decoded into electrical data that was sent by the first circuit. The PDOE can accomplish decoding based on a plurality of decoding techniques. In embodiments, the PDOE comprises a grating coupler. The grating coupler separates different polarizations in the PMB from each other. The separated polarizations of light can be sent to optical receivers that convert the optical data to electrical data. In a usage example an optical receiver can comprise a photodiode. In another embodiments, the PDOE comprises a polarization filter. A polarization filter can enable passage of light with a polarization that is compatible with the polarization filter while substantially filtering out light with polarizations that are incompatible with the polarization filter. In further embodiments, the PDOE comprises a polarization multiplexor (PMUX). The PMUX separates light that includes two or more polarizations. In a usage example, the received light is separated into two or more beams where each beam is based on a single polarization. In embodiments, the decoding includes separating, by a polarized beam splitter (PBS), the PMB into at least two polarized optical signals, wherein the separating is based on a plane of polarization of the PMB. In a usage example, the beam splitter can reflect light associated with a first polarization and transmit light associated with a second polarization. The system 700 includes a second circuit 718. The second circuit can be a circuit substantially similar or different than the first circuit. The first circuit and the second circuit can comprise separate cores, cores on a wafer, chiplets, SoCs, wafers, interposers, ASICs, and so on. The first circuit and the second circuit can comprise circuits within same or different chips, a chiplets, SoCs, wafers, interposers, etc. The first circuit and the second circuit can comprise processors, multi-core processors, memory controllers, memory chips such as DDR or HBM, I/O chips, AI accelerators, switching chips, and so on. In a usage example, the first chiplet and the second chiplet comprise artificial intelligence (AI) accelerators. In a second usage example, the first chiplet and the second chiplet comprise switching chiplets. The second chiplet can be substantially different in function, type of chip, pin layout, etc. than the first chiplet. The second chiplet can be collocated within a plurality of chiplets that also includes the first chiplet. The second chiplet can be located remotely from the first chiplet.

The system 700 includes a sending component 720. The sending component is configured to send electrical data, by the first circuit, to the VCSEL. The data can be sent by the first circuit to the VCSEL using one or more of wires, interconnect, metal layers, etc. The metal layers can include metal layers within a circuit board, a wafer, an interposer, and so on. The metal layers, which enable interconnection between and among circuit, chiplets, and other elements, can be fabricated on or within a circuit board, wafer, or interposer. Using the metal layers can offer significant communications speed due to short wire lengths, and reduced “parasitics” such as resistance, capacitance, and inductance. The VCSEL can emit light based on the sent data. The emitted light represents the data as optical data. The emitted light can be modulated.

The system 700 includes a modulating component 730. The modulating component is configured to modulate a polarization of the VCSEL, wherein the modulating includes emitting, by the VCSEL, a polarization-modulated beam (PMB), wherein the PMB is based on the electrical data that was sent. The PMB can include a beam with a plurality of polarizations. In a usage example, the PMB can include two polarizations, where one polarization represents a logic one and the second polarization represents a logic zero. In another usage example, two polarizations can represent two different serial data streams. The first circuit can send data to other surface-emitting light sources that can be modulated such as light emitting diodes (LEDs), laser diodes (LDs), and the like. The PMB can include an s-polarization. For s-polarization, the electric field of the modulated light is normal to a surface of incidence. The PMB can include p-polarization. For p-polarization, the electric field of the modulated light is parallel to the surface of incidence.

The system 700 includes a coupling optically component 740. The coupling optically component 740 is configured to couple optically the PMB to the optical medium. The optical medium can include a low loss optical medium appropriate for sending the PMB. In embodiments, the optical medium comprises a waveguide. The optical medium can also include an optical fiber. In embodiments, the optical medium comprises a polarization maintaining fiber. The coupling optically is accomplished using an optical coupler. A variety of optical couplers can be used, as described above.

The system 700 includes a decoding component 750. The decoding component 750 is configured to decode, by the PDOE, the PMB into the electrical data that was sent. The PDOE can separate distinct polarizations of light from the PMB. The polarizations can be based on an s-polarization, a p-polarization, and so on. The separated polarizations of light, which are based on optical data, can be decoded into electrical data. The decoded electrical data is the data that was sent by the first circuit. As described above and throughout, the PDOE can accomplish decoding based on a plurality of decoding techniques, such as a grating coupler, a polarization filter, a polarization mux, and so on.

The system 700 includes a delivering component 760. The delivering component 760 is configured to deliver the electrical data to the second circuit. The electrical data can be delivered by the delivering component to the second circuit using wire, interconnect, metal layers, fiberoptic cable, and so on. The metal layers can include metal layers within a circuit board, a wafer, an interposer, and so on. The metal layers, which enable interconnection between and among circuits, chiplets and other elements, can be fabricated on or within a board, wafer, interposer, etc. As was the case for sending the data from the first circuit to the VCSEL, using the metal layers can offer significant communications speed due to short wire lengths, and reduced “parasitics” such as resistance, capacitance, and inductance. The second circuit can process the delivered data, forward the delivered data, etc.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
sending electrical data, by a first circuit, to a vertical-cavity surface-emitting laser (VCSEL);
modulating a polarization of the VCSEL, wherein the modulating includes emitting, by the VCSEL, a polarization-modulated beam (PMB), wherein the PMB is based on the electrical data that was sent;
coupling optically the PMB to an optical medium, wherein the optical medium is further coupled to a polarization-dependent optical element (PDOE);
decoding, by the PDOE, the PMB into the electrical data that was sent; and
delivering the electrical data to a second circuit.

2. The method of claim 1 wherein the modulating is based on asymmetric current injection.

3. The method of claim 1 wherein the optical medium comprises a waveguide.

4. The method of claim 3 wherein the coupling optically is accomplished by a grating coupler.

5. The method of claim 3 wherein the coupling optically is accomplished by a mirror.

6. The method of claim 3 further comprising angling the PMB that was emitted by the VCSEL, wherein the angling is based on a micro-optical element (MOE).

7. The method of claim 6 wherein the MOE comprises a micro lens.

8. The method of claim 6 wherein the MOE comprises a diffractive optical element.

9. The method of claim 6 wherein the MOE comprises a Fresnel lens.

10. The method of claim 6 wherein the MOE comprises an asymmetric non-focusing optical device.

11. The method of claim 1 wherein the PDOE comprises a grating coupler.

12. The method of claim 1 wherein the PDOE comprises a polarization filter.

13. The method of claim 1 wherein the PDOE comprises a polarization multiplexor (PMUX).

14. The method of claim 13 wherein the decoding includes separating, by a polarized beam splitter (PBS), the PMB into at least two polarized optical signals, wherein the separating is based on a plane of polarization of the PMB.

15. The method of claim 14 wherein the PBS is within the PMUX.

16. The method of claim 14 transforming each optical signal within the at least two polarized optical signals, by a unique photodiode, to an electrical signal, wherein the transforming results in at least two electrical signals.

17. The method of claim 16 further comprising assembling the at least two electrical signals into a single electrical signal, wherein the single electrical signal comprises the electrical data that was sent.

18. The method of claim 1 wherein the optical medium comprises a polarization maintaining fiber.

19. The method of claim 1 wherein the VCSEL includes a ferroelectric liquid crystal layer (FLC).

20. An apparatus for transmitting data comprising:
a first circuit, wherein the first circuit sends electrical data to a vertical-cavity surface-emitting laser (VCSEL), and wherein the VCSEL emits a polarization-modulated beam (PMB) based on asymmetrically injecting current into an active region within the VCSEL;
an optical medium, wherein the PMB is coupled optically, via an optical coupler, to the optical medium;
a polarization-dependent optical element (PDOE), wherein the PDOE is further coupled to the optical medium, wherein the PDOE decodes the PMB into the electrical data that was sent; and
a second circuit, wherein the second circuit receives the electrical data that was sent.

21. The apparatus of claim 20 wherein the first circuit and the second circuit comprise a first chiplet and a second chiplet, respectively.

22. The apparatus of claim 21 wherein the first chiplet, the second chiplet, and the VCSEL are within a plurality of chiplets bonded to a front side of a photonic wafer-scale interposer (PWSI), wherein the PWSI includes a plurality of waveguides, and wherein the optical medium comprises a waveguide within the plurality of waveguides.

23. The apparatus of claim 22 wherein the PWSI comprises an optical wafer-scale AI accelerator, wherein one or more chiplets within the plurality of chiplets comprise one or more artificial intelligence (AI) accelerators.

24. The apparatus of claim 22 wherein the PWSI comprises an optical wafer-scale network switch, wherein one or more chiplets within the plurality of chiplets comprise one or more switching chiplets.

25. A system for transmitting data comprising:
a first circuit, wherein the first circuit is coupled to a vertical-cavity surface-emitting laser (VCSEL);
an optical medium, wherein light emitted from the VCSEL is coupled optically, via an optical coupler, to the optical medium;
a polarization-dependent optical element (PDOE), wherein the PDOE is further coupled to the optical medium; and
a second circuit;
wherein the system is configured to:
send electrical data, by the first circuit, to the VCSEL;
modulate a polarization of the VCSEL, wherein the modulating includes emitting, by the VCSEL, a polarization-modulated beam (PMB), wherein the PMB is based on the electrical data that was sent;
couple optically the PMB to the optical medium;
decode, by the PDOE, the PMB into the electrical data that was sent; and
deliver the electrical data to the second circuit.
